(19) United States
(12) Patent Application Publication
(10) Pub. No.: US 2026/0068726 A1
(43) Pub. Date: Mar. 5, 2026

(54) POLYIMIDE DIE SUBSTRATE

(71) Applicant: TEXAS INSTRUMENTS INCORPORATED, Dallas, TX (US)

(72) Inventors: Chu-Yun LO, Taipei City (TW); Chia Wei CHANG, Taoyuan City (TW); Jin Keong LIM, Kuala Lumpur (MY)

(21) Appl. No.: 18/821,847

(22) Filed: Aug. 30, 2024

(51) Int. Cl. H01L 23/14; H01L 21/48; H01L 23/00; H01L 23/31; H01L 23/498; H01L 25/00; H01L 25/065

(52) U.S. Cl. CPC H01L 23/145

(57) ABSTRACT

In examples, a semiconductor package comprises a semiconductor die having a device side including circuitry and a non-device side opposing the device side. The semiconductor package comprises a polyimide substrate coupled to the non-device side of the semiconductor die by an adhesive layer. The semiconductor package comprises a conductive terminal coupled to the polyimide substrate by the adhesive layer, and a bond wire coupled to the device side of the semiconductor die and to the conductive terminal. The semiconductor package comprises a mold compound covering the semiconductor die, the polyimide substrate, the bond wire, and at least part of the conductive terminal, with the conductive terminal extending to an exterior of the mold compound.

### BACKGROUND

A semiconductor package may include a semiconductor die and a housing to cover the semiconductor die. The semiconductor package may further include conductive terminals exposed to an exterior surface of the housing. The conductive terminals are coupled to the semiconductor die. The conductive terminals provide electrical pathways between circuitry on the semiconductor die and components (e.g., printed circuit boards) outside of the semiconductor package.

### SUMMARY

In examples, a semiconductor package comprises a semiconductor die having a device side including circuitry and a non-device side opposing the device side. The semiconductor package comprises a polyimide substrate coupled to the non-device side of the semiconductor die by an adhesive layer. The semiconductor package comprises a conductive terminal coupled to the polyimide substrate by the adhesive layer, and a bond wire coupled to the device side of the semiconductor die and to the conductive terminal. The semiconductor package comprises a mold compound covering the semiconductor die, the polyimide substrate, the bond wire, and at least part of the conductive terminal, with the conductive terminal extending to an exterior of the mold compound.

In examples, a method for manufacturing a semiconductor package comprises singulating a semiconductor wafer to produce a semiconductor die, with the semiconductor die having a device side in which circuitry is formed and a non-device side opposing the device side. The method also comprises coupling the non-device side of the semiconductor die to a non-conductive tape using an adhesive layer, coupling a conductive terminal to the non-conductive tape using the adhesive layer, coupling a bond wire to the device side of the semiconductor die and to the conductive terminal, and covering the semiconductor die, the conductive terminal, the bond wire, and the non-conductive tape with a mold compound.

### BRIEF DESCRIPTION OF THE DRAWINGS

FIGS. 1A-1E are top-down, profile cross-sectional, profile, and perspective views of a semiconductor package including a polyimide die substrate, in accordance with various examples.

FIG. 2 is a flow diagram of a method for manufacturing a semiconductor package including a polyimide die substrate, in accordance with various examples.

FIG. 3 is a flow diagram of a method for manufacturing a semiconductor package including a polyimide die substrate, in accordance with various examples.

FIGS. 4A-4F4 are a process flow diagram of a process for manufacturing a semiconductor package including a polyimide die substrate, in accordance with various examples.

### DETAILED DESCRIPTION

Multi-chip modules, or MCMs, are specialized electronic packages that include multiple integrated circuits (ICs) per package. The MCM provides advantages over other package types, such as increased performance by reducing latency between ICs, a more compact and lightweight design, enhanced reliability with fewer interconnects, improved power efficiency by minimizing distances between ICs, and potential cost savings in high-volume production. MCMs are widely used in applications requiring high performance, compact size, and reliability, such as telecommunications, computing, aerospace, and military systems. MCMs also are useful in applications requiring voltage isolation between ICs, such as in some power applications.

However, MCMs also present numerous disadvantages. For instance, each package requires its own specific die pad design to accommodate a specific die placement, which can increase design time, costs, and hardware complexity. Further, in MCMs for isolation applications, dies cannot be positioned near the edge of the conductive die pad, as doing so can generate undesirable electric fields at the package edge or even extending outside of the package. This undesirably restricts design flexibility. In addition, in isolation applications the die pad must be divided into two or more segments instead of being a monolithic whole, each segment corresponding to a different die and a different voltage domain. The dies must be separated by a minimum threshold distance to preserve voltage isolation. Furthermore, the process of preventing RBO (Red Box Oxide) formation on the die attach pad after mounting the dies can result in epoxy flow to undesirable areas, diminishing manufacturing yield.

This disclosure describes various examples of a semiconductor package including a semiconductor die substrate formed of a non-conductive tape, such as a polyimide, rather than a metal (e.g., copper). The polyimide substrate may have a minimum thickness of 50 microns to provide rigidity and mechanical strength to support the structures mounted on the substrate. Multiple semiconductor dies, which may be configured to operate in separate voltage domains, may be coupled to the substrate, with no gap in between the semiconductor dies, and with no minimum required distance between the semiconductor dies. The device sides of the semiconductor dies may be wire bonded to conductive terminals. A mold compound may cover the substrate, the multiple semiconductor dies, the bond wires, and at least portions of the conductive terminals. Because the substrate is formed of a non-conductive tape, there is no need for customized die pads, thereby saving design time and costs and minimizing complexity. Further, because the substrate is a non-conductive tape, mitigation of electric fields at the package periphery is not necessary, and the semiconductor dies may be positioned more flexibly throughout the package, including near the edges of the non-conductive tape. Further, the non-conductive tape need not be divided into multiple segments for different voltage domains. Rather, multiple semiconductor dies configured to operate in separate voltage domains may be coupled to the same monolithic piece of non-conductive tape (e.g., polyimide), thus increasing simplicity in design and manufacture. Furthermore, RBO mitigation measures are unnecessary with the non-conductive tape, and thus the technical challenges that accompany RBO mitigation measures are eliminated.

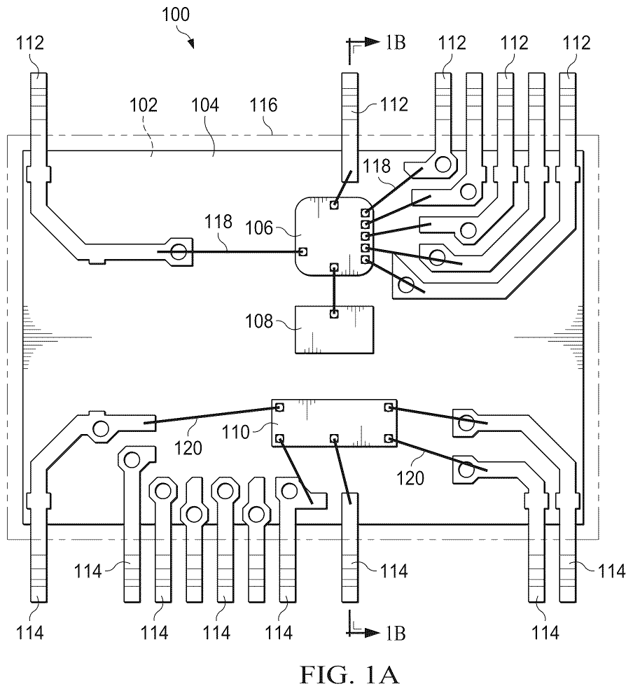

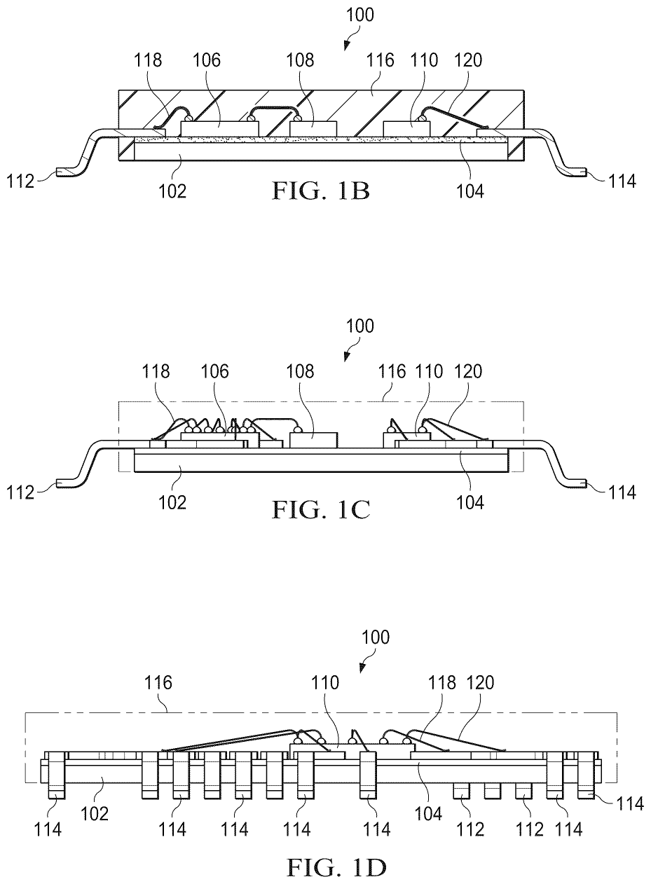

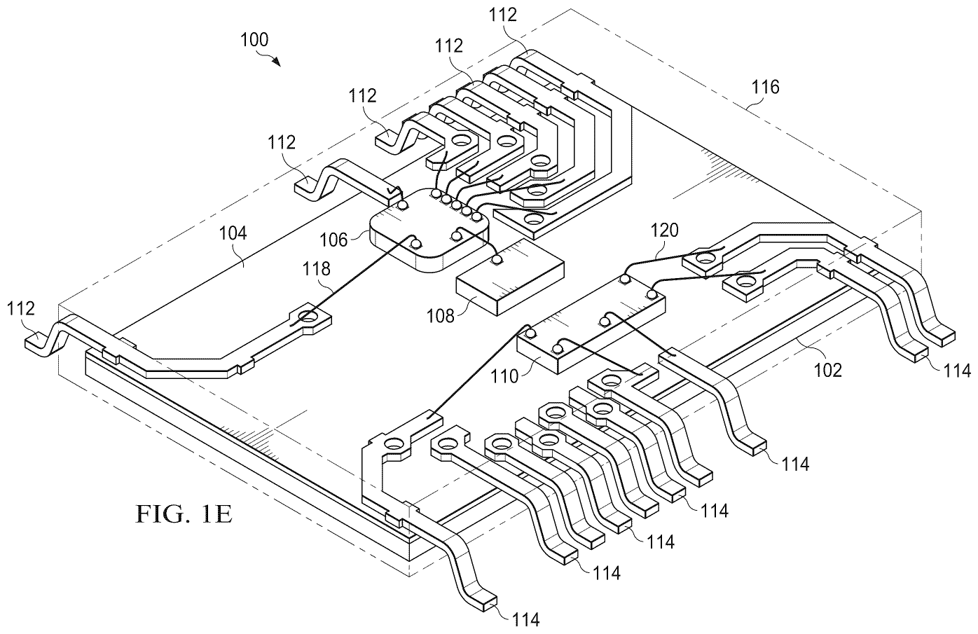

FIGS. 1A-1E are top-down, profile cross-sectional, profile, and perspective views of a semiconductor package including a polyimide die substrate, in accordance with various examples. In particular, FIG. 1A is a top-down view of a semiconductor package 100, in accordance with various examples. The semiconductor package 100 includes a polyimide die substrate 102. The polyimide die substrate 102 includes the term “polyimide,” but in examples, the die substrate 102 may be composed of any non-conductive material, and the polyimide die substrate 102 may also be referred to herein as a non-conductive die substrate, a non-conductive substrate, a die substrate, a polyimide substrate, or a substrate. An adhesive layer 104 is coupled to a top surface of the polyimide die substrate 102. The semiconductor package 100 includes semiconductor dies 106, 108, and 110. One or more of the semiconductor dies 106, 108, 110 may be configured to operate in different voltage domains than one or more of the remaining semiconductor dies 106, 108, 110. By “different voltage domains” or analogous terms, it is meant that one or more semiconductor dies operates electrically independently from one or more other semiconductor dies, with no electrical connections, including ground connections, being shared therebetween. In the specific example of FIG. 1A, the semiconductor dies 106, 108 are configured to operate in a first voltage domain, and the semiconductor die 110 is configured to operate in a second voltage domain. The adhesive layer 104 couples the polyimide die substrate 102 to each of the semiconductor dies 106, 108, 110.

The semiconductor package 100 may include multiple conductive terminals, or “leads,” 112, 114. The conductive terminals 112, 114 may have a gullwing-style shape, although the scope of this disclosure is not limited as such. The conductive terminals 112 extend from within a mold compound 116 that covers the various aforementioned components of the semiconductor package 100 to an exterior of the mold compound 116, as shown. Similarly, the conductive terminals 114 extend from within the mold compound 116 to the exterior of the mold compound 116, as shown. Bond wires 118 may couple the semiconductor dies 106, 108 to each other, and the bond wires 118 may further couple the semiconductor die 106 to the conductive terminals 112. Bond wires 120 may couple the semiconductor die 110 to the conductive terminals 114. Because the semiconductor dies 106, 108 are configured to operate in a different voltage domain than the semiconductor die 110, and further because the semiconductor dies 106, 108 are coupled to the conductive terminals 112 while the semiconductor die 110 is coupled to the conductive terminals 114, the conductive terminals 112, 114 are also configured to operate in separate voltage domains. Different configurations than the specific configuration shown in FIG. 1A are contemplated and included in the scope of this disclosure.

As described above, the polyimide die substrate 102 may be composed of any suitable, non-conductive material, such as polyimide. Other example materials of which the polyimide die substrate 102 may be composed in lieu of polyimide include build-up films, such as AJINOMOTO^{®}build-up film (ABF) and similar mold compound materials. As explained, regardless of the specific material of which the polyimide die substrate 102 is composed, it may be referred to herein as a polyimide die substrate 102 for consistency. The polyimide die substrate 102 is used to provide structural support for one or more semiconductor dies in lieu of structures such as metal die pads. For example, instead of coupling a semiconductor die to a metal die pad using die attach material, the semiconductor die may be coupled to the polyimide die substrate 102 using an adhesive layer 104. Examples of the adhesive used in the adhesive layer 104 may include heat-curable adhesives. In some examples, the adhesive layer 104 may be composed of a combination of one or more adhesives.

As explained above, the polyimide die substrate 102 is included in the semiconductor package 100 in lieu of a metal die pad, and in some examples, the semiconductor package 100 lacks a metal die pad. More precisely, the polyimide die substrate 102 is not coupled to a metal substrate (or die pad) that is parallel to a horizontal plane in which the monolithic, non-conductive, polyimide substrate 102 lies.

The polyimide die substrate 102 must have adequate rigidity to structurally support the semiconductor dies coupled thereto, such as the semiconductor dies 106, 108, 110. An inadequately rigid polyimide die substrate 102 will fail to maintain coupling to the semiconductor dies 106, 108, 110, causing detachment at the connection points to the semiconductor dies 106, 108, 110. Further, an inadequately rigid polyimide die substrate 102 will fail to maintain bond wire connections, such as to bond wires 118, 120. The mold compound 116 will experience problems with structural integrity, such as cracking. Generally, an inadequately rigid polyimide die substrate 102 will have catastrophic effects on the structural and functional integrity of the semiconductor package 100. Accordingly, the rigidity of the polyimide die substrate 102 must be greater than the corresponding wire bending stress, with a rigidity below this threshold being disadvantageous for at least the reasons described above. Further, this rigidity of the polyimide die substrate 102 is achievable by ensuring the thickness of the polyimide die substrate 102 is at least 50 microns. A thickness of the polyimide die substrate 102 less than 50 microns results in the rigidity problems described above. The adhesive layer 104 has a thickness ranging from 10 microns to 20 microns, with a thickness below this range being disadvantageous because of resultant weak adhesive strength, and with a thickness above this range being disadvantageous because the adhesive layer could float over the die surface.

Because the polyimide die substrate 102 is non-conductive, semiconductor dies configured to operate in differing voltage domains may be co-located on that polyimide die substrate 102, without any gaps in the polyimide die substrate 102 between such semiconductor dies. The polyimide die substrate 102 is a monolithic structure rather than multiple separate structures and rather than two or more structures joined together by coupling (e.g., an adhesive or other coupling member).

FIG. 1B is a profile, cross-sectional view of the structure of FIG. 1A, in accordance with various examples. As shown, the adhesive layer 104 contacts a top surface of the polyimide die substrate 102. (As used herein, the term “contact” means physical contact between two or more items.) The semiconductor dies 106, 108, 110 have device sides in which circuitry is formed, and these device sides face away from the polyimide die substrate 102 and the adhesive layer 104. The bond wires 118, 120 are coupled to these device sides. The semiconductor dies 106, 108, 110 also include non-device sides opposing the device sides. The non-device sides of the semiconductor dies 106, 108, 110 face toward the polyimide die substrate 102 and the adhesive layer 104. The non-device sides of the semiconductor dies 106, 108, 110 are approximately co-planar with bottom surfaces of the conductive terminals 112, 114, with the bottom surfaces of the conductive terminals 112, 114 facing the monolithic, non-conductive substrate 102.

Each of the semiconductor dies 106, 108, 110 is coupled to a different portion of the polyimide die substrate 102 by way of a different portion of the adhesive layer 104. The different portions of the polyimide die substrate 102 that couple to different semiconductor dies 106, 108, 110 (via the adhesive layer 104) are not separated by gaps, but rather are part of a monolithic polyimide die substrate 102. Similarly, the different portions of the adhesive layer 104 that couple to different semiconductor dies 106, 108, 110 are not separated by gaps, but rather are part of a monolithic adhesive layer 104. Such monolithic structures are faster, less expensive, and more efficient to manufacture and use and are made possible by the fact that the polyimide die substrate 102 and the adhesive layer 104 are non-conductive, thus enabling the coupling of the semiconductor dies 106, 108, 110 to common, monolithic structures despite operating in different voltage domains.

FIG. 1C is a profile view of the structure of FIG. 1A, in accordance with various examples. FIG. 1D is a profile view of the structure of FIG. 1A, in accordance with various examples. FIG. 1E is a perspective view of the structure of FIG. 1A, in accordance with various examples.

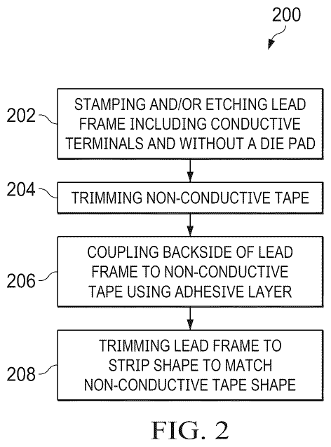

FIG. 2 is a flow diagram of a method 200 for manufacturing a semiconductor package including a polyimide die substrate, in accordance with various examples. More specifically, the method 200 includes steps for manufacturing a lead frame which, in turn, is useful to manufacture a semiconductor package including a polyimide die substrate, in accordance with various examples. The method 200 includes stamping and/or etching a lead frame including conductive terminals (e.g., leads) and without a die pad (202). The conductive terminals of the lead frame may be coupled to each other by tie bars, for example. However, a metal die pad is absent. The conductive terminals may be composed of any suitable metal or alloy, such as copper, and may be formed using any suitable technique, such as stamping, etching, or other techniques.

The method 200 includes trimming a non-conductive tape, such as a polyimide tape (204). For example, a polyimide tape having relatively large dimensions in the x-y plane (e.g., length and width) may be trimmed to more readily match the dimension(s) of the lead frame manufactured in step 202. For instance, an example lead frame manufactured in step 202 may be a strip of considerable length x centimeters and may have a width that is y microns. Accordingly, a polyimide tape, or other suitable, non-conductive tape, may be trimmed such that its length is approximately x centimeters and such that its width is approximately y microns. In some examples, trimming the non-conductive tape also may include trimming the non-conductive tape in the z-direction, meaning trimming the thickness of the non-conductive tape.

The method 200 may include coupling a backside of the lead frame to the non-conductive tape using an adhesive layer (206). For example, an adhesive layer, having been trimmed to have x-y dimensions similar to those of the non-conductive tape, may be applied to the non-conductive tape, and then the resulting assembly may be coupled to a backside of the lead frame produced in step 202 using the adhesive layer. In some examples, trimming the adhesive layer also may include trimming the adhesive layer in the z-direction, meaning trimming the thickness of the adhesive layer.

The method 200 may include optionally trimming the lead frame into a strip shape to match the shape of the non-conductive tape (208), in case the lead frame has not already been trimmed into a strip and in case the lead frame dimensions do not already approximately match those of the non-conductive tape. For example, if the non-conductive tape has a length x centimeters and a width y microns, and if the lead frame has dimension(s) larger than x and y, the lead frame may be trimmed to approximately match x and y. Trimming the lead frame after coupling the lead frame to the non-conductive tape has an advantage in that the appropriate lead frame dimensions may be easily achieved by using the non-conductive tape as a stencil.

Accordingly, the method 200 produces a structure that includes a lead frame strip having conductive terminals and a non-conductive die substrate coupled to the lead frame strip. This structure may be subsequently useful in the method 300, described below, to form a semiconductor package having a non-conductive (e.g., polyimide) die substrate.

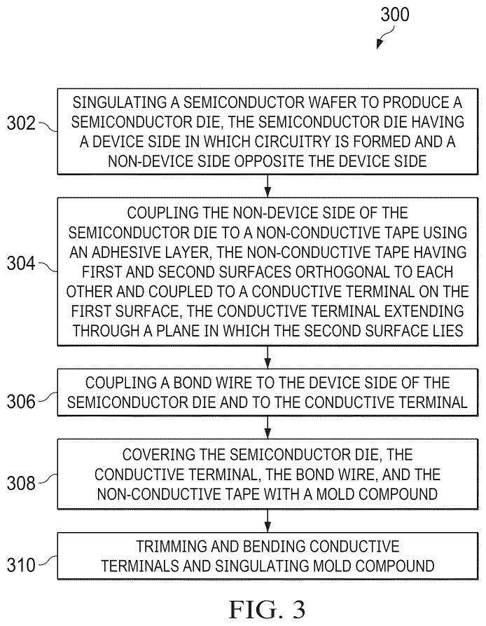

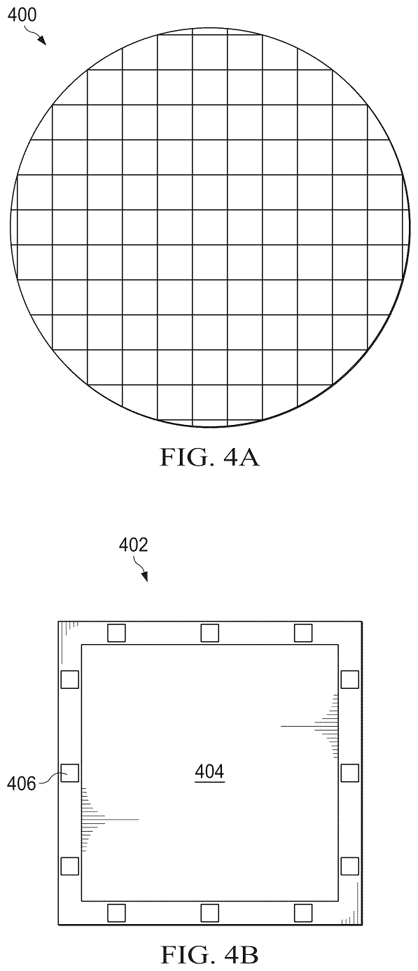

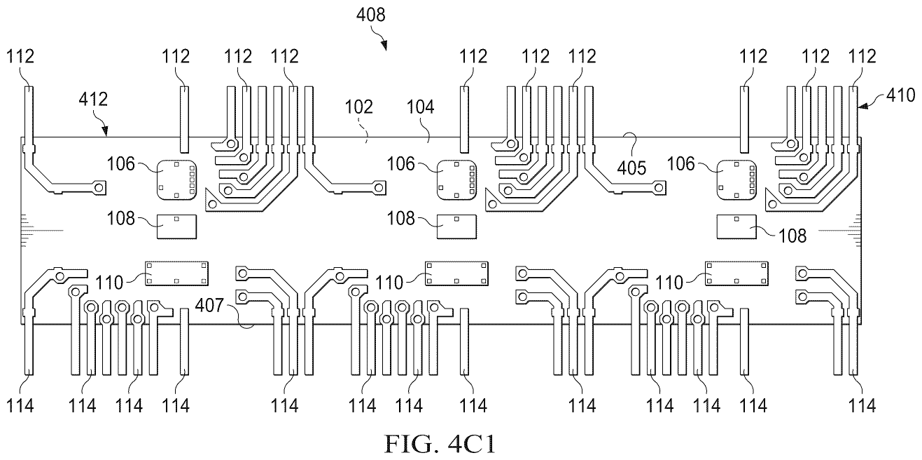

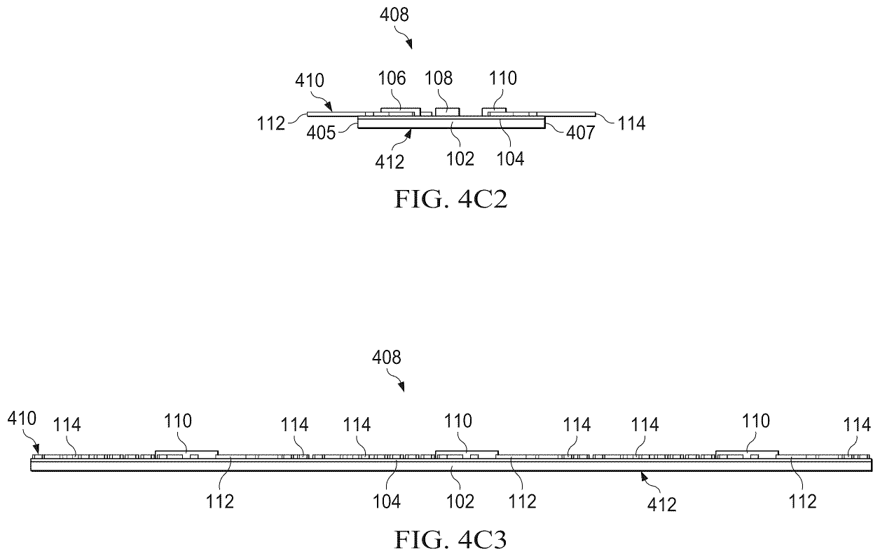

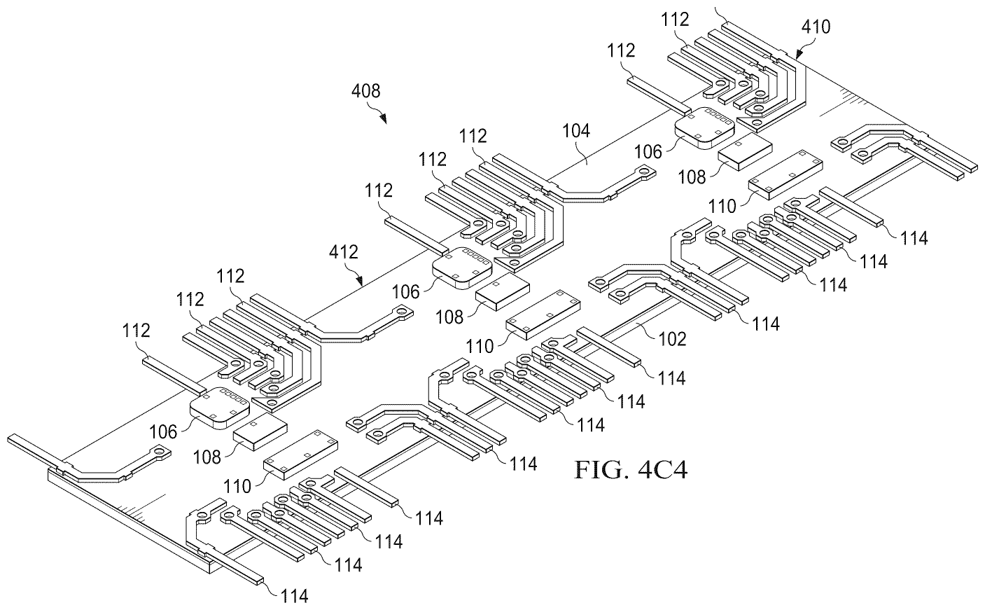

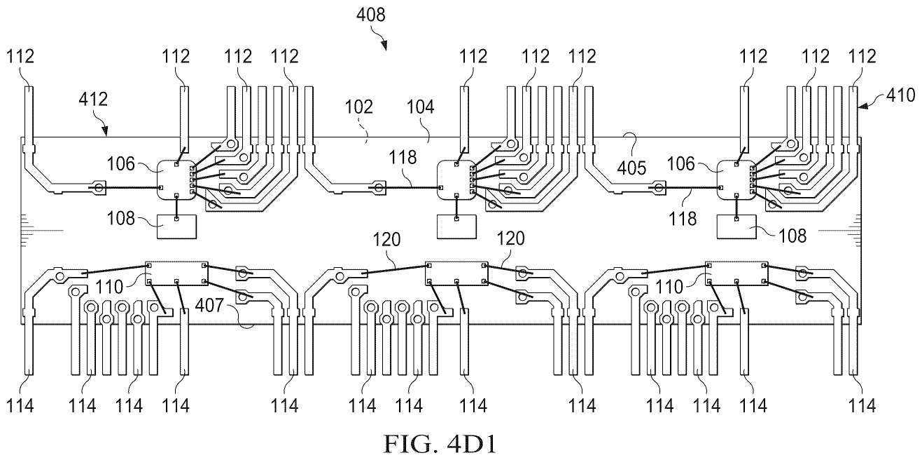

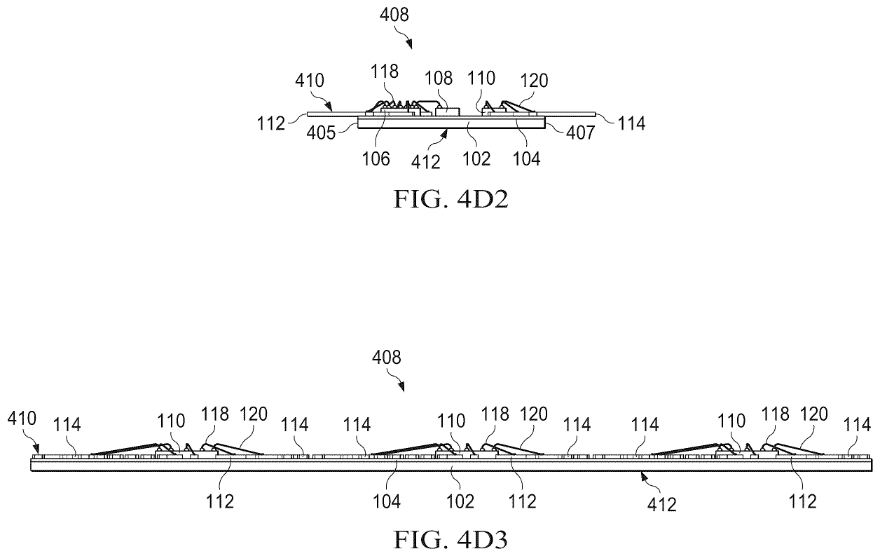

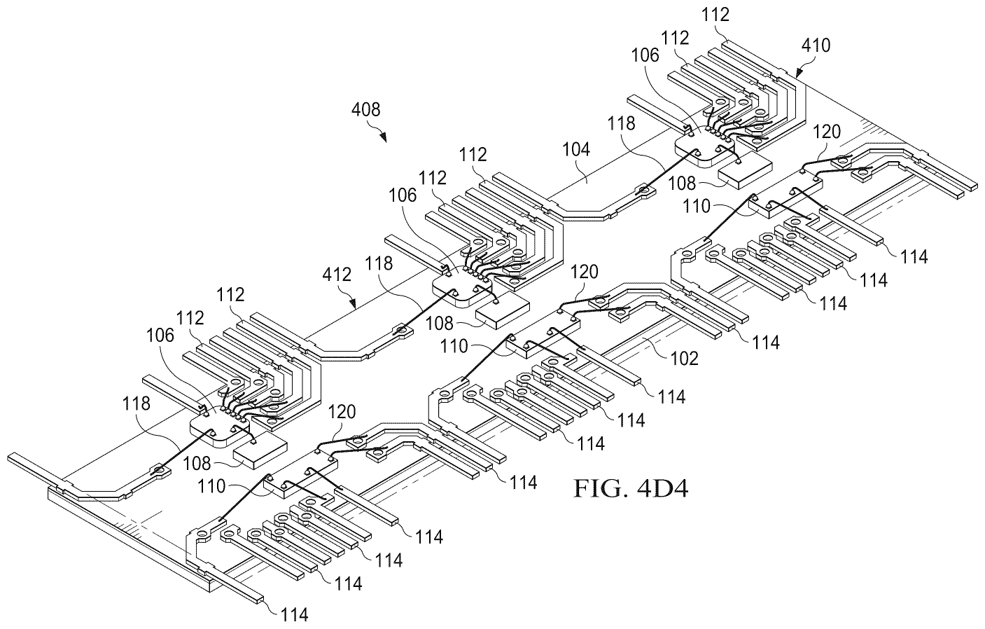

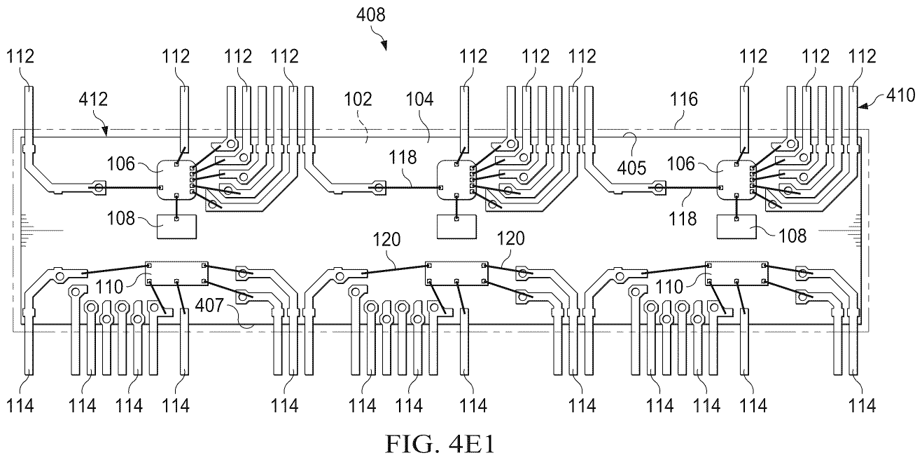

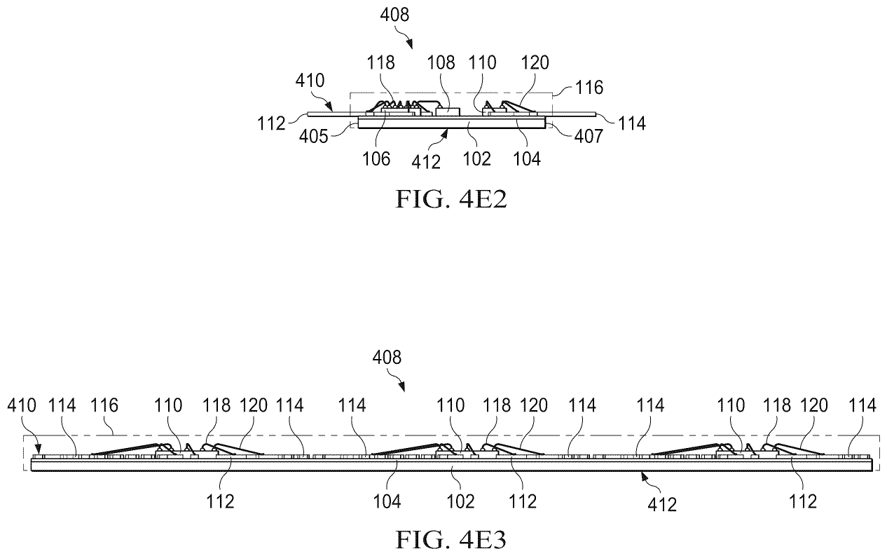

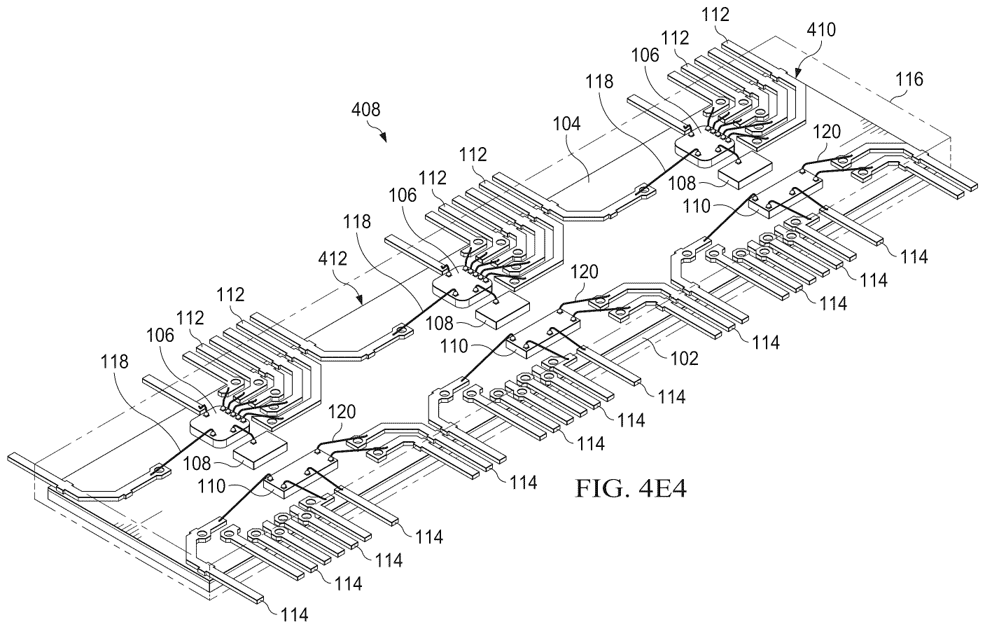

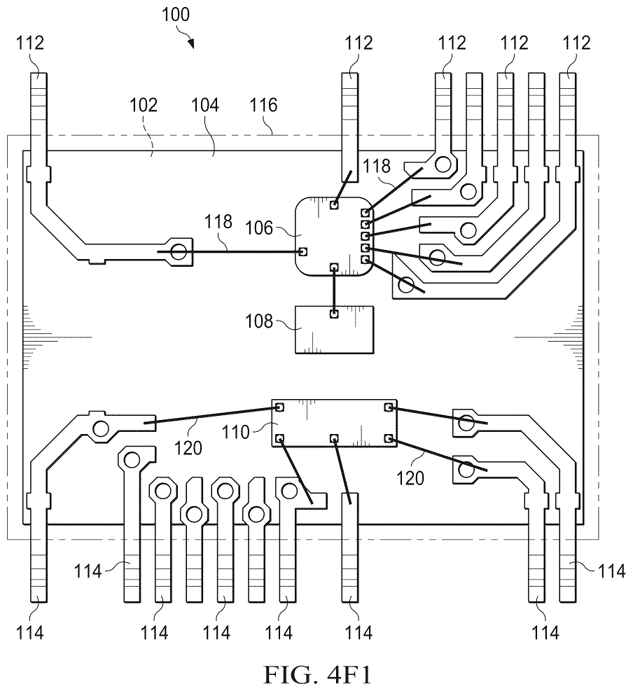

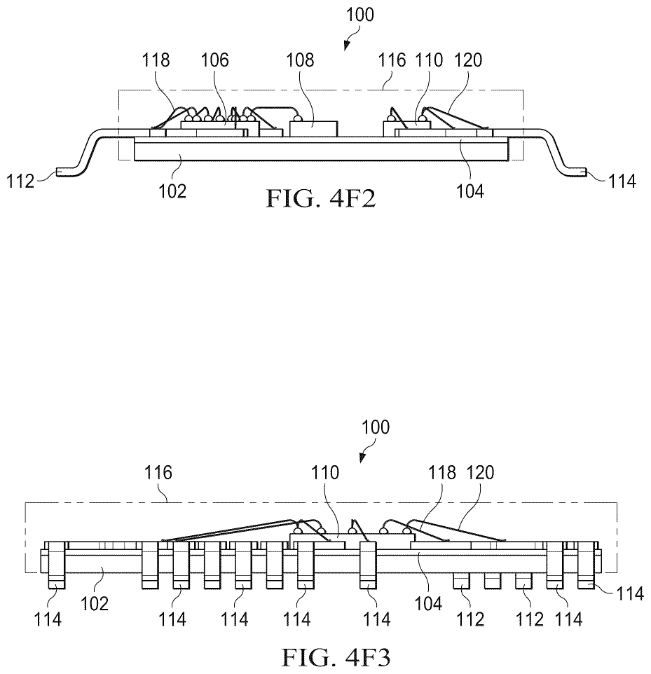

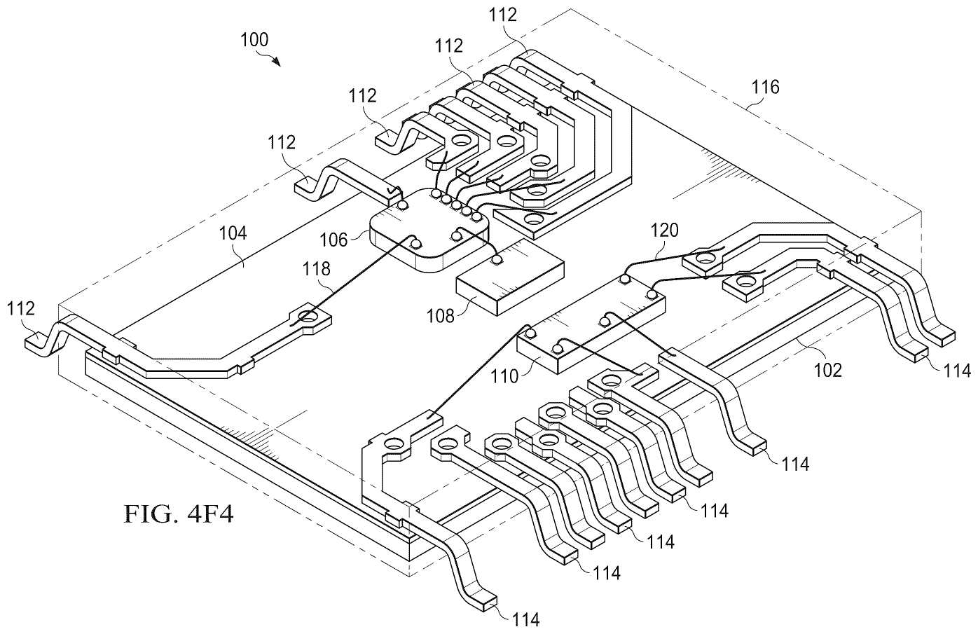

FIG. 3 is a flow diagram of a method 300 for manufacturing a semiconductor package including a polyimide die substrate, in accordance with various examples. FIGS. 4A-4F4 are a process flow diagram of a process for manufacturing a semiconductor package including a polyimide die substrate, in accordance with various examples. Accordingly, FIGS. 3 and 4A-4F4 are now described in parallel.

The method 300 includes singulating a semiconductor wafer (e.g., silicon, gallium nitride) to produce a semiconductor die, with the semiconductor die having a device side in which circuitry is formed and a non-device side opposing the device side (302). FIG. 4A depicts a semiconductor wafer 400, and FIG. 4B depicts a semiconductor die 402 produced by singulating the semiconductor wafer 400 (e.g., by a mechanical or laser saw). The semiconductor die 402 may have a device side 404 and bond pads 406, as shown, although the scope of this disclosure is not limited to any particular type of semiconductor die. Circuitry may be formed in and/or on the device side 404. The bond pads 406 may be electrically coupled to various parts of the circuitry.

The method 300 includes coupling the non-device side of the semiconductor die to a non-conductive tape using an adhesive layer, with the non-conductive tape having first and second surfaces orthogonal to each other and coupled to a conductive terminal on the first surface, with the conductive terminal extending through a plane in which the second surfaces lies (304). FIG. 4C1 is a top-down view of the structure resulting by performance of step 304. The structure 408 includes a lead frame strip 410 (tie and dam bars omitted from view for clarity) coupled to a non-conductive tape 412. For example, the conductive terminals 112, 114 may be part of the lead frame strip 410, and that lead frame strip 410 may be coupled to the non-conductive tape 412, as described in method 200. Furthermore, semiconductor dies produced in step 302 (e.g., FIGS. 4A and 4B), such as the semiconductor dies 106, 108, 110 (FIG. 1A), may be coupled to the non-conductive tape 412 using an adhesive layer, such as the adhesive layer 104 (FIGS. 1A, 1B). The non-conductive tape 412 has a first, top surface (facing the lead frame strip 410) and a second, side surface 405 orthogonal to the first, top surface. The second, side surface 405 of the non-conductive tape 412 lies in a first plane, and some of the conductive terminals 112, 114, extend through that first plane. A second plane, parallel to the first plane, contains another side surface 407 of the non-conductive tape 412, and some of the conductive terminals 112, 114 extend through this second plane. FIG. 4C2 is a profile view of the structure of FIG. 4C1, in accordance with various examples. FIG. 4C3 is another profile view of the structure of FIG. 4C1, in accordance with various examples. FIG. 4C4 is a perspective view of the structure of FIG. 4C1, in accordance with various examples.

The method 300 includes coupling a bond wire to the device side of the semiconductor die and to the conductive terminal (306). FIG. 4D1 is a top-down view of the structure of FIG. 4C1, except that bond wires 118, 120 have been coupled to the semiconductor dies 106, 108, 110 and to the conductive terminals 112, 114, as shown. Other configurations of bond wire connections are contemplated and included in the scope of this disclosure. Further, various types of bonds are contemplated and included in the scope of this disclosure, such as ball bonds, stitch bonds, etc. FIG. 4D2 is a profile view of the structure of FIG. 4D1, in accordance with various examples. FIG. 4D3 is another profile view of the structure of FIG. 4D1, in accordance with various examples. FIG. 4D4 is a perspective view of the structure of FIG. 4D1, in accordance with various examples.

The method 300 includes covering the semiconductor die, the conductive terminal, the bond wire, and the non-conductive tape with a mold compound (308). FIG. 4E1 is a top-down view of the structure of FIG. 4D1, except that the mold compound 116 has been applied to the structure, as shown, and in accordance with various examples. The mold compound 116 may be applied using any suitable technique, such as by using a mold chase and mold injection system. FIG. 4E2 is a profile view of the structure of FIG. 4E1, in accordance with various examples. FIG. 4E3 is another profile view of the structure of FIG. 4E1, in accordance with various examples. FIG. 4E4 is a perspective view of the structure of FIG. 4E1, in accordance with various examples.

The method 300 includes trimming and bending the conductive terminals and singulating the mold compound to produce individual semiconductor packages (310). FIG. 4F1 shows an example structure that may result from trimming and bending the conductive terminals 112, 114 of FIG. 4E1 and by singulating the mold compound 116 to produce individual semiconductor packages 100. FIG. 4F2 is a profile view of the structure of FIG. 4F1, in accordance with various examples. FIG. 4F3 is another profile view of the structure of FIG. 4F1, in accordance with various examples. FIG. 4F4 is a perspective view of the structure of FIG. 4F1, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a first semiconductor die having a first device side including first circuitry and a first non-device side opposing the first device side, the first semiconductor die configured to operate in a first voltage domain;
a second semiconductor die having a second device side including second circuitry and a second non-device side opposing the second device side, the second semiconductor die configured to operate in a second voltage domain different than the first voltage domain;
a non-conductive substrate coupled to the first and second non-device sides of the first and second semiconductor dies, respectively, by an adhesive layer;
first and second conductive terminals coupled to the non-conductive substrate by the adhesive layer;
a first bond wire coupled to the first device side of the first semiconductor die and to the first conductive terminal;
a second bond wire coupled to the second device side of the second semiconductor die and to the second conductive terminal; and
a mold compound covering the first and second semiconductor dies, the non-conductive substrate, the first and second bond wires, and at least parts of the first and second conductive terminals, the first and second conductive terminals extending to an exterior of the mold compound.

2. The semiconductor package of claim 1, wherein the non-conductive substrate is not coupled to a metal substrate that is parallel to a horizontal plane in which the non-conductive substrate lies.

3. The semiconductor package of claim 1, wherein the first non-device side of the first semiconductor die and the second non-device side of the second semiconductor die are approximately co-planar with bottom surfaces of the first and second conductive terminals, the bottom surfaces of the first and second conductive terminals facing the non-conductive substrate.

4. The semiconductor package of claim 1, wherein the non-conductive substrate comprises polyimide.

5. The semiconductor package of claim 1, wherein the non-conductive substrate is at least 50 microns thick.

6. The semiconductor package of claim 1, wherein the adhesive layer includes a heat curable adhesive.

7. The semiconductor package of claim 1, wherein the non-conductive substrate is monolithic.

8. A semiconductor package, comprising:
a semiconductor die having a device side including circuitry and a non-device side opposing the device side;
a polyimide substrate coupled to the non-device side of the semiconductor die by an adhesive layer;
a conductive terminal coupled to the polyimide substrate by the adhesive layer;
a bond wire coupled to the device side of the semiconductor die and to the conductive terminal; and
a mold compound covering the semiconductor die, the polyimide substrate, the bond wire, and at least part of the conductive terminal, the conductive terminal extending to an exterior of the mold compound.

9. The semiconductor package of claim 8, wherein the polyimide substrate is not coupled to a metal substrate that is parallel to a horizontal plane in which the polyimide substrate lies.

10. The semiconductor package of claim 8, wherein the non-device side of the semiconductor die is approximately co-planar with a bottom surface of the conductive terminal, the bottom surface of the conductive terminal facing the polyimide substrate.

11. The semiconductor package of claim 8, further comprising a second semiconductor die having a second device side including second circuitry and a second non-device side opposing the second device side, wherein the second non-device side is coupled to the polyimide substrate by the adhesive layer.

12. The semiconductor package of claim 11, wherein the second device side is coupled to a second conductive terminal by a second bond wire.

13. The semiconductor package of claim 11, wherein the semiconductor die and the second semiconductor die are in separate voltage domains.

14. The semiconductor package of claim 13, wherein a portion of the polyimide substrate to which the semiconductor die is coupled and a second portion of the polyimide substrate to which the second semiconductor die is coupled are not separated by a gap in the polyimide substrate.

15. The semiconductor package of claim 8, wherein the polyimide substrate has a thickness of at least 50 microns.

16. A method for manufacturing a semiconductor package, comprising:
singulating a semiconductor wafer to produce a semiconductor die, the semiconductor die having a device side in which circuitry is formed and a non-device side opposing the device side;
coupling the non-device side of the semiconductor die to a non-conductive tape using an adhesive layer;
coupling a conductive terminal to the non-conductive tape using the adhesive layer;
coupling a bond wire to the device side of the semiconductor die and to the conductive terminal; and
covering the semiconductor die, the conductive terminal, the bond wire, and the non-conductive tape with a mold compound.

17. The method of claim 16, wherein the non-conductive tape comprises polyimide.

18. The method of claim 16, wherein the non-conductive tape has a minimum thickness of 50 microns.

19. The method of claim 16, wherein the semiconductor package does not include a metallic die pad to which the semiconductor die is coupled.

20. The method of claim 16, wherein the adhesive layer includes a heat-curable adhesive.

21. The method of claim 16, further comprising coupling a second semiconductor die to the non-conductive tape using the adhesive layer, the semiconductor die and the second semiconductor die configured to operate in different voltage domains.

22. The method of claim 21, wherein a first portion of the non-conductive tape to which the semiconductor die is coupled and a second portion of the non-conductive tape to which the second semiconductor die is coupled are not separated by a gap in the non-conductive tape.
